(19) United States
(12) Patent Application Publication
(10) Pub. No.: US 2014/0191770 A1
(43) Pub. Date: Jul. 10, 2014

(54) CAPACITIVE SENSING DEVICE

(71) Applicant: Jean-Noel LEFEBVRE, Lyon (FR)

(72) Inventor: Jean-Noel LEFEBVRE, Lyon (FR)

(21) Appl. No.: 14/153,344

(22) Filed: Jan. 13, 2014

Related U.S. Application Data
(63) Continuation of application No. PCT/FR2012/051603, filed on Jul. 6, 2012.

(30) Foreign Application Priority Data
Jul. 13, 2011 (FR) 11/56393

(51) Int. Cl. G01R 27/26

(52) U.S. Cl. CPC G01R 27/2605
USPC 324/681

(57) ABSTRACT

A capacitive sensing device including logic components and a capacitive sensor having at least one electrode, said logic components and capacitive sensor being arranged to form an oscillator, where the capacitive sensor includes a plurality of capacitive sensing electrodes, as well as a selector arranged to form an oscillator selectively from a plurality of possible oscillators, by connecting the logic components with respectively, in the case of each oscillator formed, a given combination from the plurality of electrodes of the capacitive sensor including at least an emission electrode and a reception electrode forming a capacitor formed by means of mutual electrostatic coupling.

### CROSS REFERENCE TO RELATED APPLICATIONS

This application is a continuation of International Patent Application Number PCT/FR2012/051603 filed on 6 Jul. 2012 which claims priority to French Patent Application Number 11/56393 filed on 13 Jul. 2011, where both of said applications are herein incorporated by reference in their entirety.

### TECHNICAL FIELD

The present invention relates to a capacitive sensing device comprising logic components and capacitive sensor comprising at least one electrode, the logic components and the capacitive sensor being arranged to form an oscillator.

### BACKGROUND

Such a type of device is known, for example from document US2003/0028346.

This type of device is satisfactory in that it allows obtaining a sensing by processing the signals from the oscillator, by analyzing a characteristic amount of this signal constituted for example by changes in the signal frequency.

However, it is desirable to allow in some cases using a sensing on a plurality of sensing electrodes. The invention seeks to provide a solution allowing to simplify the device structure while allowing reliable sensing on a plurality of electrodes.

### BRIEF SUMMARY

For this purpose, the invention is a device according to the above-mentioned type, characterized in that the capacitive sensor comprises a plurality of capacitive sensing electrodes, the device further comprises a selector arranged to selectively form an oscillator from a plurality of possible oscillators by connecting logic components, comprising at least one inverter logic component, and a follower logic component, with respectively, in the case of each formed oscillator, a given combination among the plurality of electrodes of the capacitive sensor comprising at least one transmitting electrode and one receiving electrode forming a capacitance by mutual electrostatic coupling.

These arrangements allow performing sensing on a plurality of electrodes combinations forming mutual capacitance by limiting the number of components used by using for each oscillator a combination of logic components and a combination of electrodes.

According to one aspect of the invention, the selector is arranged to sequentially form different oscillators in a pre-set time sequence.

According to various aspects of the invention:
a current limiting component is arranged at the output of the inverter component, between the inverter component and the follower component;
the capacitive sensor is arranged in parallel with the follower component;
the circuit thus formed is a positive feedback circuit.
   the device includes an information feedback loop arranged between the follower component output and the inverter component input.

It should be noted that the oscillators formed are logic gate astable multivibrator-type oscillators.

The current limiting component, which allows controlling the charging time of the formed mutual capacitance, can in particular comprise a resistive component or an assembly of switchable current sources.

These arrangements allow forming oscillators from simple and inexpensive components not requiring complex settings, which further allows obtaining reliable sensing based on the oscillator frequency analysis.

According to one aspect of the invention, the plurality of electrodes comprises a receiving or transmitting electrode common to a set of electrode combinations formed among the plurality of electrodes of the capacitive sensor.

These arrangements allow obtaining a simple configuration of electrodes positioning. In particular, this configuration is particularly suitable in the case where the sensing of the positioning of an element must be performed relative to a control surface, on which a common electrode can be positioned, the distinct electrodes of each combination being arranged at the periphery of the control surface.

According to one aspect of the invention, the plurality of electrodes forms a matrix structure, the selector being arranged to form a set of oscillators each comprising an electrode combination formed by a pair of electrodes comprising a transmitting electrode and a receiving electrode.

These arrangements allow in particular performing sensing on a touch panel.

According to one aspect of the invention, the selector is arranged to form an oscillator with a combination of electrodes comprising a first transmitting electrode, and a second transmitting electrode, a mutual capacitance being measured relative to a receiving electrode.

These arrangements allow in particular increasing the sensing accuracy compared to a configuration wherein a pair comprising a single transmitting electrode and a receiving electrode is used.

According to one aspect of the invention, the second transmitting electrode is fed in phase with the first transmitting electrode.

These arrangements allow in particular sensing a movement or the distance of an element according to a transverse direction to a surface on which the considered electrodes are positioned.

According to one aspect of the invention, the second transmitting electrode is fed in anti-phase with the first transmitting electrode.

These arrangements allow increasing the sensing sensitivity in parallel with the surface on which the electrodes are arranged.

According to one aspect of the invention, the first transmitting electrode and the receiving electrode, on the one hand, and the second transmitting electrode, on the other hand, are arranged on either side of a control surface.

These arrangements allow performing sensing of a position or a movement relative to a control surface without requiring the positioning of electrodes on said control surface. These arrangements can be applied for example in the case where the control surface is a display area. In particular, this display area can be formed by a screen, for example an LCD, TFT, LED, OLED-type screen, or an area equipped with means for electronic ink display.

According to one aspect of the invention, a first pair of electrodes and a second pair of electrodes are disposed on either side of the control surface, the selector being arranged to selectively form:
a first oscillator comprising a first transmitting electrode formed by the transmitting electrode of the first pair, and a second transmitting electrode formed by the transmitting electrode of the second pair, a mutual capacitance being measured relative to the receiving electrode of the first pair, and
a second oscillator comprising a first transmitting electrode formed by the transmitting electrode of the first pair, and a second transmitting electrode formed by the transmitting electrode of the second pair, a mutual capacitance being measured relative to the receiving electrode of the second pair.

According to one aspect of the invention, the device comprises a first set of electrodes comprising the first transmitting electrode, the receiving electrode and the second transmitting electrode disposed spaced apart according to a first direction, and a second set comprising a first transmitting electrode, a receiving electrode and a second transmitting electrode disposed spaced apart according to a second direction.

According to one aspect of the invention, the device comprises logic components distributed in portions of circuits associated with an electrode or a combination of electrodes.

According to one aspect of the invention, each circuit portion is disposed close to a pair of electrodes so as to form an oscillator with said electrode pair and comprising connections between said circuit portions so as to allow for sensing by a given receiving electrode associated with a circuit portion a transmission by a first transmitting electrode associated with the same circuit portion and a second transmitting electrode fed by another circuit portion.

According to one aspect of the invention, at least one electrode is used as a transmitting or receiving electrode according to the device configurations selected by the selector.

According to one aspect of the invention, the device comprises a plurality of electrodes disposed on the edges of a screen, especially a touch screen.

According to one aspect of the invention, the device comprises an electrode disposed above the screen and several peripheral electrodes. This electrode can be used in particular as a transmitting electrode. In this configuration, the analysis comprises using alternately peripheral electrodes as receiving electrodes.

According to one aspect of the invention, the device comprises a voltage level adjustment component disposed upstream of a transmitting electrode.

According to one aspect of the invention, the adjustment component is arranged to raise the level of voltage supplied to the transmitting electrode.

The sensing distance depends on the voltage at the terminals of the electrodes. It is therefore desirable to increase the supply voltage to increase the sensing distance. However, energy consumption increases with the square of this voltage. With the aforementioned arrangement, it is possible to increase the voltage only for the supply to the transmitting electrodes, without the need to use a circuit having a high working voltage. Thus, the circuit comprising most logic components operates at a first low voltage, and only the voltage amplification component or buffer requires a higher supply voltage. The overall consumption of the circuit is therefore slightly increased compared to the sensing distance gain obtained.

According to one aspect of the invention, the adjustment component is arranged to set a nominal frequency operating point for the oscillator.

These arrangements allow in particular adjusting the nominal frequency to adapt it to the frequency range that can be accepted by an oscillator signal processing unit. These arrangements also allow changing the working frequency to perform a spread spectrum. Indeed, some standards require limiting an emitted field within a given frequency range over a given period. A sufficiently frequent change in the working frequency allows facilitating the compliance with these standards.

According to one aspect of the invention, the device comprises a signal processing unit for the analysis of the characteristics of an oscillator signal, and in particular the oscillator frequency.

### BRIEF DESCRIPTION OF THE DRAWINGS

In any case, the invention will be better understood with the following description, with reference to the appended schematic drawing showing, by way of non limiting examples, various embodiments of a device according to the invention.

FIG. 1 is a block diagram showing some elements of the invention.

FIG. 2 is a partial electric diagram of a first device according to the invention.

FIG. 3 is a diagram of the electrodes positioning in the device of FIG. 2.

FIG. 4a is a partial electric diagram of a second device according to the invention.

FIG. 4b shows a partial variant of the diagram of FIG. 4.

FIG. 5 is a partial electric diagram of a third device according to the invention.

FIG. 6 is a diagram of the electrodes positioning in the device of FIG. 5.

FIG. 7 is a partial electric diagram of a fourth device according to the invention.

FIG. 8 is a diagram of the electrodes positioning in the device of FIG. 5.

FIG. 9 is a partial electric diagram of a fifth device according to the invention.

FIG. 10 is a partial electric diagram of a sixth device according to the invention.

FIG. 11 is a diagram illustrating an operating mode of the device of FIG. 10.

FIG. 12 shows a diagram equivalent to the diagram of FIG. 11.

FIG. 13 illustrates an embodiment of a current limiting component.

FIG. 14 is a diagram of the electrodes positioning in a seventh device according to the invention.

FIG. 15 is a diagram of the electrodes positioning in an eighth device according to the invention.

### DETAILE DESCRIPTION

In the following description, in order to simplify explanation, we indicate that some control signals are at a level of 1 or 0 to designate high or low levels that may correspond for example to two voltage levels, high and low, of a given electronic circuit.

To illustrate the operation of the various devices according to the invention, it should be noted that the selector SL enables to choose at a moment to connect the sensor DT so as to form an oscillator with the selected electrodes of this sensor and the logic components of the device.

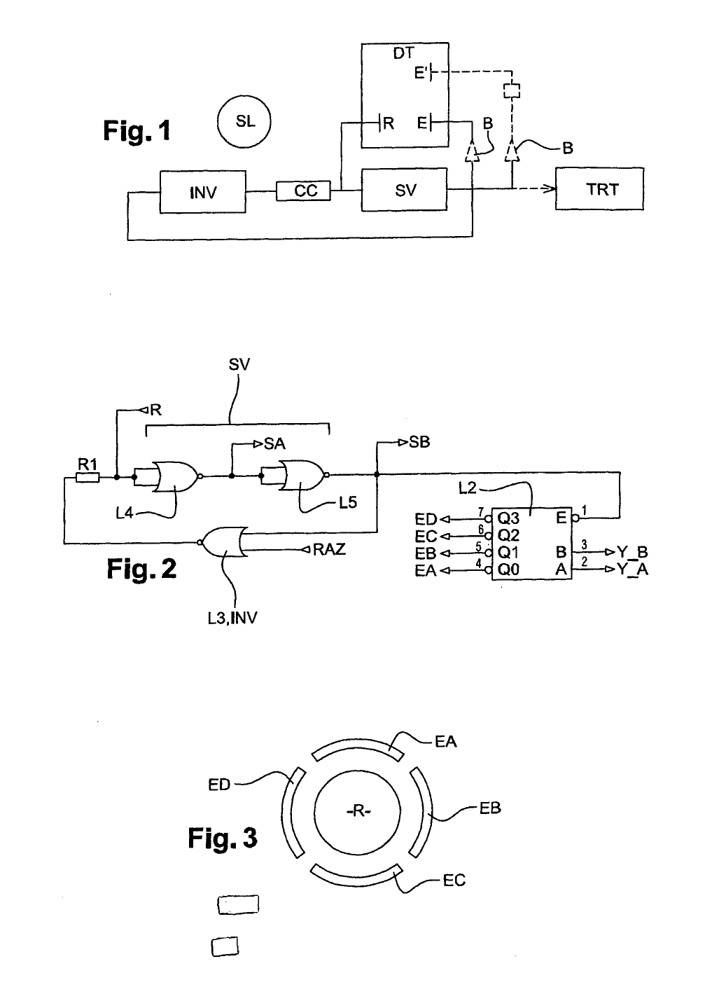

When a particular mode of selection is chosen, the electrical diagram of the device is equivalent to an oscillator. We show by way of example an oscillator that can be formed by reference to FIG. 1.

This oscillator comprises an inverter logic component INV, the output of which is connected to a current limiting component CC. At the output of the current limiting component CC, a follower logic component SV is disposed. The output of this follower logic component SV is on the one hand fed back to the input of inverter component INV and to at least one transmitting electrode of the sensor DT. At least one receiving electrode is connected to a point of the circuit thus formed between the current limiting component and the follower logic component SV.

These arrangements allow forming an oscillator with the electrodes of the sensor DT, the oscillation frequency of which depends on the value of the relative capacitance formed between at least one transmitting electrode and at least one receiving electrode forming part of the sensor.

Thus, by analyzing, in a processing unit TRT, the oscillator signals and in particular the oscillation frequency, it is possible to perform sensing based on the change in the observed frequency.

The measurement point of the signal(s) supplied to the processing unit varies according to the embodiments reported below.

The current limiting component CC can be in particular comprised of a resistor, or by an assembly of switchable current sources as shown in FIG. 13, which includes the function of the inverter component and the current limiting function.

In particular, such an assembly based on current sources comprises two parallel branches sharing the same input and the same output.

A first branch comprises an inverter component INV and a current source I+ controlled by the output of the inverter component. The current source is disposed in the forward direction between a positive reference of the circuit and the assembly output.

A second branch comprises a follower component SV and a current source I− controlled by the output of the follower component. The current source is disposed in the reverse direction between the assembly output and the circuit ground.

On this block diagram, if an input set as 1 is present, the inverter component INV has an output set as O and the follower component SV has an output set as 1. Accordingly, it is the current source I− connected in a reverse direction which is activated.

On this block diagram, if an input set as 0 is present, the inverter component INV has an output set as 1 and the follower component SV has an output set as 0. Accordingly, it is the current source I+ connected in the forward direction which is activated.

Thus, this assembly behaves as an inverter component INV associated with a current limiting component CC.

In addition, other components or elements can be added to allow optimizing the circuit as we will see it later.

For example, it can be considered to add at least another follower element or buffer B in order to raise or lower the level of voltage supplied to at least one transmitting electrode or to adjust the output voltage level to set the operating point in terms of device frequency. This element is shown in dotted lines on the branch connecting the transmitting electrodes of the sensor. This component B should be positioned after the bypass designed to form a return to the inverter component INV at the output of the follower component SV.

Furthermore, it is possible to use an oscillator in which at least two transmitting electrodes E and E are taken into account, the signal emitted by the two electrodes can be in particular in phase or in anti-phase.

It should be noted that the oscillators formed are logic gate astable multivibrator-type oscillators. This type of oscillators does not comprise any frame connected to ground.

The advantages of this type of oscillator include in particular the following:
without any frame to ground, this oscillator shows little sensitivity regarding to surrounding masses and to stray capacitances compared to ground.
no switching of analogue signals is required
logic gate astable multivibrator oscillators exhibit good independence to fluctuations in supply voltage, unlike “ring” and “relaxation” type oscillators
unlike ring oscillators, the frequency is highly dependent on gate propagation delay; in fact, in a logic gate astable multivibrator oscillator it is mainly the elements RC which determine the frequency.

We will now outline various examples of devices incorporating the above-mentioned principles.

According to a first embodiment shown in FIGS. 2 and 3, the device is designed to perform sensing based on four pairs of electrodes (Ea , R), (Eb, R), (Ec, R) and (Ed, R), all of these electrode pairs sharing the same receiving electrode referred to as R and having a different transmitting electrode Ra to Rd.

This device comprises the following logic components. An inverter component INV is comprised of a NOR gate L3. A follower component SV is formed by two NOR gates L4 and L5 in series the inputs of which are connected to the same point so as to form two inverters.

The selector SL in this example is comprised of a follower demultiplexer L2. The selector SL is controlled to emit to one or other of the four transmitting electrodes RA to RD according to two signals Y_A and Y_B from a microcontroller, not shown.

The signal to be supplied to the processing unit TRT is one of the SA and SB signals corresponding respectively to the outputs of the two L4 and L5 gates.

With regard to the processing unit used for analyzing the signal, it can be comprised of a device as described in patent EP2087591B1. It is, however, also possible to use other types of processing unit, for example such as the unit described in document US2003/0028346 using a counting method.

FIG. 3 illustrates the positioning of the device electrodes. It appears that these arrangements allow in particular performing movement sensing and/or calculation of spatial coordinates in two or three dimensions relative to a control surface on which the receiving electrode R is disposed.

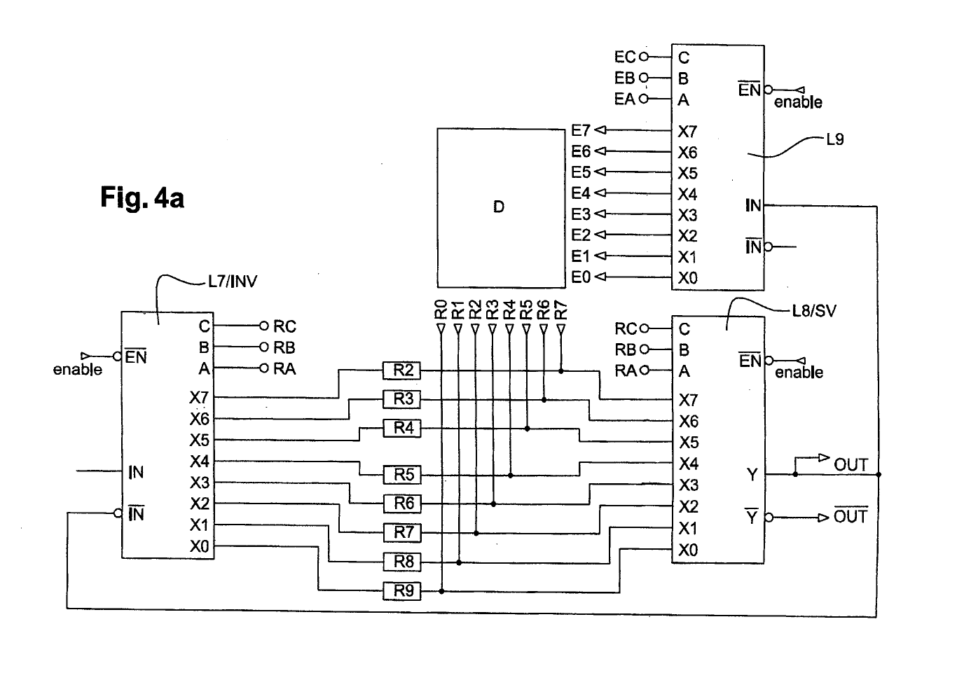

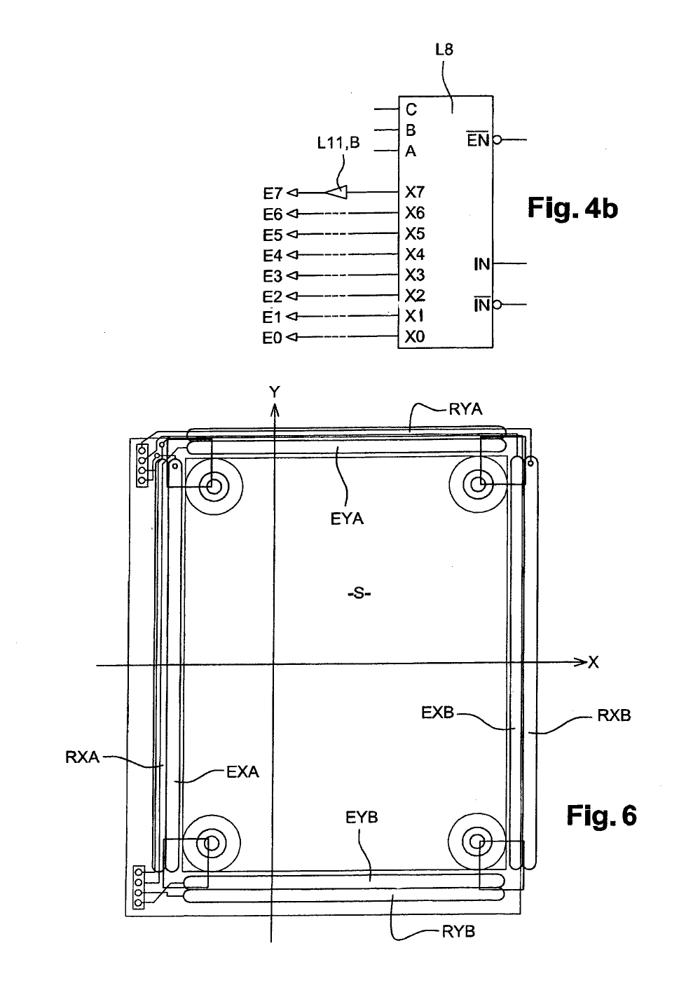

According to a second embodiment shown in FIG. 4, the capacitive sensor comprises a plurality of electrodes forming a matrix structure disposed close to the surface of a touch panel D, using for example transparent electrodes made of ITO (indium-tin oxide). A plurality of transmitting electrodes E0 to E7 is disposed according to a first direction substantially parallel to each other. A second plurality of receiving electrodes E0 to E7 is disposed according to a second direction substantially parallel to each other.

The inverter component INV is comprised of a demultiplexer L7 comprising an inverting input !IN.

The follower component SV is formed by a multiplexer L8.

It should be noted that each output of the demultiplexer L7 is connected to an input of the multiplexer L8, the connection branch comprising a resistor R2 to R9, and receiving at the resistor output a signal from a receiving electrode R0 to R7.

At the output of multiplexer L8 forming a follower component, a loop is formed towards the inverter demultiplexer L7 input. Furthermore, the output signal of the multiplexer is sent to a second follower demultiplexer L9, the signal being sent through this demultiplexer to a given transmitting electrode E0 to E7.

The selector SL is comprised of the two multiplexers L7 and L9 and the multiplexer L8.

This selector SL is respectively controlled regarding the components L7 and L8 by binary control signals RA, RB, RC allowing choosing a receiving electrode disposed on a branch between the demultiplexer L7 and the multiplexer L8, and regarding the multiplexer L9 by binary control signals EA, EB, EC allowing choosing a transmitting electrode.

The control signals RA, RB, RC, EA, EB, EC are supplied by a microcontroller, not shown, and allow defining at a given time an oscillator with a pair formed of a transmitting electrode E and a receiving electrode R. Pairs among all the combinations between a transmitting electrode and a receiving electrode can be formed.

The signal to be supplied to the processing unit TRT is one of the two signals OUT and !OUT corresponding respectively to the multiplexer L8 output and the inverted output signal !OUT.

FIG. 4b shows a variant of the device according to the second embodiment.

According to this variant, the voltage amplification component composed for example of a voltage step-up follower buffer L11 is disposed on each branch between the demultiplexer L8 output and each transmitting electrode.

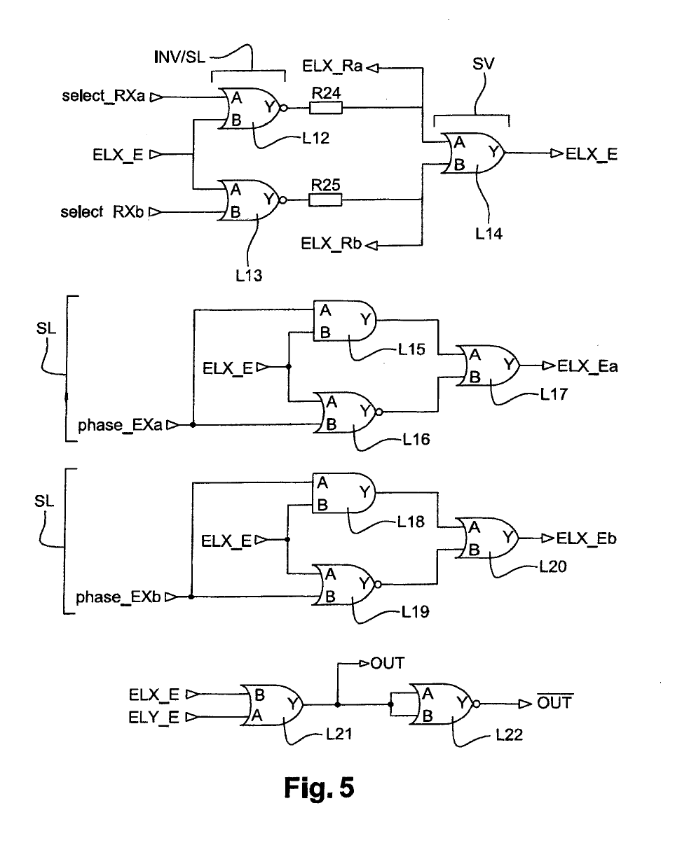

According to a third embodiment shown in FIGS. 5 and 6, it appears that the device is designed to perform movement sensing and/or a calculation of a user coordinates with respect to a control surface S, without an electrode being present on this surface.

Thus, pairs of electrodes are positioned on the periphery of this surface. In particular, in order to sense a movement according to a first X axis, a first pair of electrodes comprising a transmitting electrode EXA and a receiving electrode RXA is disposed on a first side of the control surface, and a second pair of electrodes comprising a transmitting electrode EXB and a receiving electrode RXB is disposed on a second side of the control surface S opposite the first side, the two pairs being therefore spaced apart along the first X axis.

Similarly, in order to sense a movement and/or calculate spatial coordinates according to a second Y axis perpendicular to the first X axis, a third pair of electrodes comprising a transmitting electrode EYA and a receiving electrode RYA is disposed on a third side of the control surface, and a fourth pair of electrodes comprising a transmitting electrode EYB and a receiving electrode RYB is disposed on a fourth side of the control surface S opposite the third side, the two pairs being therefore spaced apart along the second Y axis.

We will now describe the operation of the device in connection with the electrodes shown in FIG. 6. Since the system uses the same type of circuit for sensing along the X axis and along the Y axis, we will describe hereinafter only the portion which is specific to the X axis.

As can be seen in FIG. 5, the device comprises two inverter components INV comprised of two NOR gates L12 and L13, one of the inputs of each gate being connected to the same point corresponding to the same input signal referred to as ELX_E. The second input of both gates corresponds to a control input signal select_RXa or select_RXb, these two control signals allowing to select whether the receiving electrode RXa or RXb must be taken into account to form the oscillator as we will describe in detail later.

The output of the inverter component L12 is connected to a first input of a follower component SV formed by an OR gate L14. The connection branch between the component L12 output and the component L14 input comprising a resistor R24, and receiving at the resistor output a signal ELX_Ra from a receiving electrode RXa.

Meanwhile, the inverter component L13 output is connected to a second input of a follower component SV formed by an OR gate L14. The connection branch between the component L12 output and the component L14 input comprising a resistor R25, and receiving at the resistor output a signal ELX_Rb from a receiving electrode RXb.

Thus, if the signal select_RXa is at 1, and the signal select_RXb signal is at 0, a signal !ELX_E is at the output of the component L12, whereas the gate L13 is blocked. The active branch of this circuit portion is therefore the branch connected to the electrode Ra.

Otherwise, if the signal select_RXa is at 0, and the signal select_RXb is at 1, a signal !ELX_E is at the output of the component L13, whereas the gate L12 is blocked. The active branch of this circuit portion is therefore the branch connected to the electrode

Rb.

In all cases, the output of the follower component SV/L14 is fed back at the input as the signal ELX_E.

This same signal ELX_E is also supplied at the input of the second and third portions of the circuit shown in FIG. 5.

Considering the second portion of the circuit shown, the signal ELX_E is supplied to an input of a follower AND gate L15 and to an input of an inverter OR gate L16.

Furthermore, a control signal phase_EXa is applied to the second input of the follower AND gate L15 and to the second input of the NOR gate thus inverter L16.

The output of the gate L15 and the output of the gate L16 are respectively connected to both inputs of an OR gate L17, the output of this OR gate L17 being itself connected to the transmitting electrode EXA to which a signal ELX_Ea is sent.

If the control signal phase_EXa is at 1, we find the signal ELX_E at the output of the AND gate L15, whereas the output of the gate L16 remains at 0. The signal sent from the gate L17 is therefore ELX_Ea=ELX_E.

If the control signal phase_EXa is at 0, we find the signal !ELX_E at the output of the AND gate L16, whereas the output of the gate L15 remains at 0. The signal sent from the gate L17 is therefore ELX_Ea=!ELX_E.

It appears that the third portion of the circuit which enables sending a control signal ELX_Eb to the transmitting electrode EXB is similar to the second portion of the circuit, the gates L18, L19 and L20 taking over the function of the gates L15, L16 and L17, and the control signal phase EXa being replaced by the signal phase_EXb.

Thus, if the control signal phase_EXb is at 1, we find the signal ELX_E at the output of the AND gate L18, whereas the output of the gate L19 remains at 0. The signal sent from the gate L20 is therefore ELX_Eb=ELX_E.

If the control signal phase_EXb is at 0, we find the signal !ELX_E at the output of the AND gate L19, whereas the output of the gate L18 remains at 0. The signal sent from the gate L20 is therefore ELX_Eb=!ELX_E.

Accordingly, by choosing identical values for the signals phase_EXa and phase_EXb, the two transmitting electrodes EXA and EXB are fed in phase.

In contrast, if different values are chosen for the signals phase_EXa and phase_EXb, the two transmitting electrodes EXA and EXB are fed in anti-phase.

In order to provide a signal to the processing unit TRT, the fourth portion of the circuit takes the signal ELX_E and the signal ELY_E, corresponding to an oscillator possibly formed for the Y axis, these two signals being connected to the input terminals of an OR gate L21. Sensing being performed alternately on the X axis or on the Y axis, the signal being observed ELX_E or ELY_E reaches the output of the component L21 and provides a first value OUT. Thereafter, this signal is fed to both inputs of an inverter OR gate L22 to obtain a signal !OUT.

It appears that, in this embodiment, the selection function is carried out by inverter gates L12 and L13 as regards the receiving electrodes, and by the gates L15 to L120 as regards the transmitting electrodes.

The signal to be supplied to the processing unit TRT is one of the two signals OUT and !OUT corresponding respectively to the multiplexer L8 output and the inverted output signal !OUT.

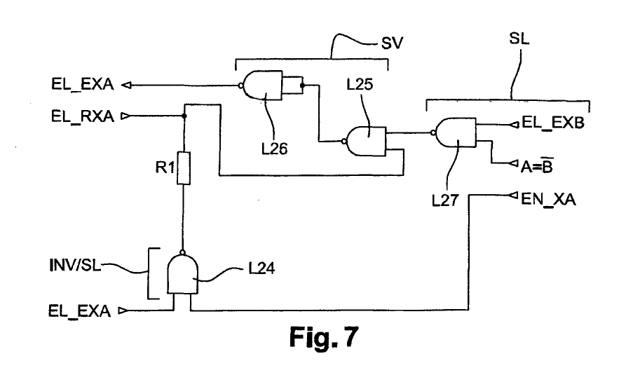

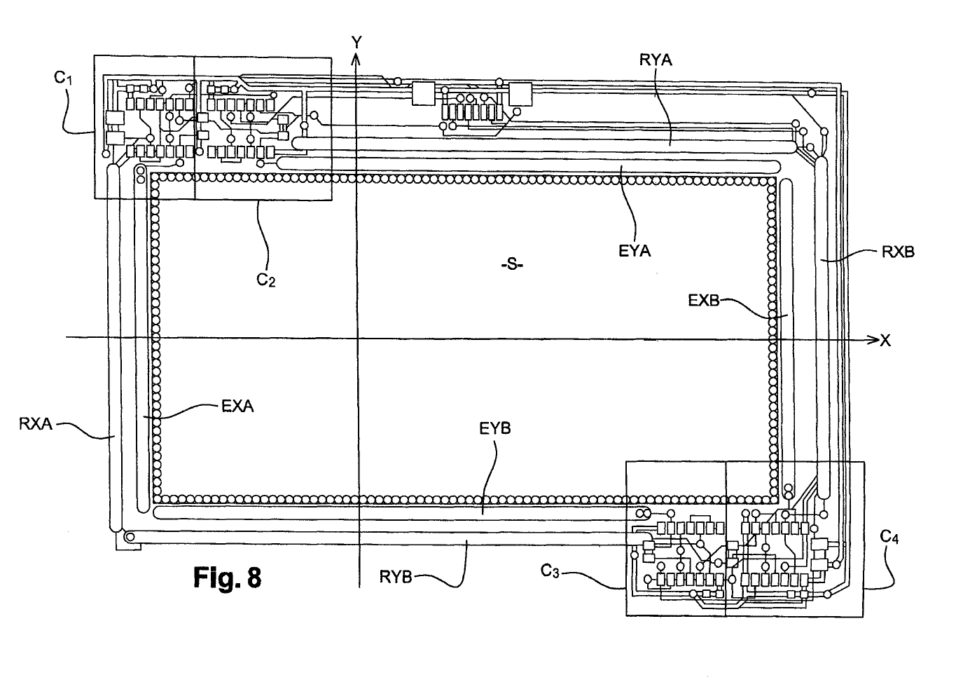

According to a fourth embodiment shown in FIGS. 7 and 8, it appears that the device is designed to perform a movement sensing and/or a calculation of spatial coordinates of an element that can in particular be a user's hand or finger or a pointing stylus handled by a user with respect to a control surface S, without an electrode being present on this surface.

Thus, pairs of electrodes are positioned at the periphery of this surface as seen in FIG. 8 in a similar manner to what is described above with reference to the third embodiment with reference to FIG. 6.

However, in this fourth embodiment, the electronic circuit is arranged so that the control of each electrode is disposed as close as possible thereto to reduce external influences on the signals from or towards the electrodes. Thus, four circuit portions C1 to C4 are arranged for the four pairs of electrodes,,,.

We will now describe the circuit portion C1 corresponding to the electrode pair with reference to FIG. 7.

An inverter component INV L24 is comprised of a NAND gate, of which one of the inputs is controlled by a signal EN_XA for indicating if an oscillation of the circuit must be allowed.

The output of the inverter component L24 is connected to a first input of a follower component SV formed by two inverter NAND gates L25 and L26 in series. The output of the NAND gate L25 is connected to both inputs of the gate L26.

The connection branch between the component L24 output and the component L25 input comprising a resistor R1, and receives at the resistor output a signal EL_RXa from a receiving electrode RXa.

The second input of the NAND gate L25 is connected to the output of a logic NAND gate L27. This gate takes at the input two signals: a signal EL_EXB from a second circuit C2 related to the electrode pairs EXB, EYB, and a control signal represented by A=!B, which indicates whether a transmission by the transmitting electrode EXA in anti-phase with respect to the electrode EXB must be performed.

The output of follower component SV formed by the output of the gate L26 forms a signal EL_EXA to be sent both on the transmitting electrode EXA and at the input of the inverter component L24.

It appears that the selector is constituted by the gate 27 and the gate L24.

Indeed, the operation of this circuit can be described as follows according to the values of the two control signals EN_XA and A=!B.

In a first operating mode, the signal EN_XA is at 1 and the signal A=!B is at 0.

In this case, the gate L24 behaves as an inverter component INV, a signal !EL_EXA being at the output of this gate. The gate L27 has its output blocked at 1, the gate L25 behaves as an inverter of its input signal, and therefore the combination of the gates L25 and L26 forms a follower SV of the signal from the receiving electrode and the inverter gate L24.

Under these conditions, an oscillator is formed with the electrode pair EXA, RXA according to a diagram similar to that of FIG. 1.

According to a second operating mode, the signal EN_XA is at 0 and the signal A=!B is at 1.

In this case, the output of the gate L24 is blocked at 1. The gate L27 behaves as an inverter component of the signal EL_EXB, a signal !EL_EXB being therefore at the output of this gate. Since the output of the gate L24 is blocked at 1, a first input of the gate L25 is at 1, the gate L25 behaves as an inverter of its input signal on its second gate, and therefore the combination of the gates L25 and L26 forms a follower of the signal !EL_EXB from the inverter gate L27.

Accordingly, under these conditions, the circuit C1 does not form an oscillator, but the electrode EXA is fed in anti-phase with the electrode EXB as EL_{‘}EXA=EL_EXB.

It should be noted that in this fourth embodiment, the selector is distributed over the four circuit portions.

The signals which are communicated from a circuit portion to another one correspond to output signals of an oscillator at the output of a logic gate. The output signals of the receiving electrodes are treated logically as close as possible to the electrodes, thus avoiding external disturbances and improving sensing accuracy.

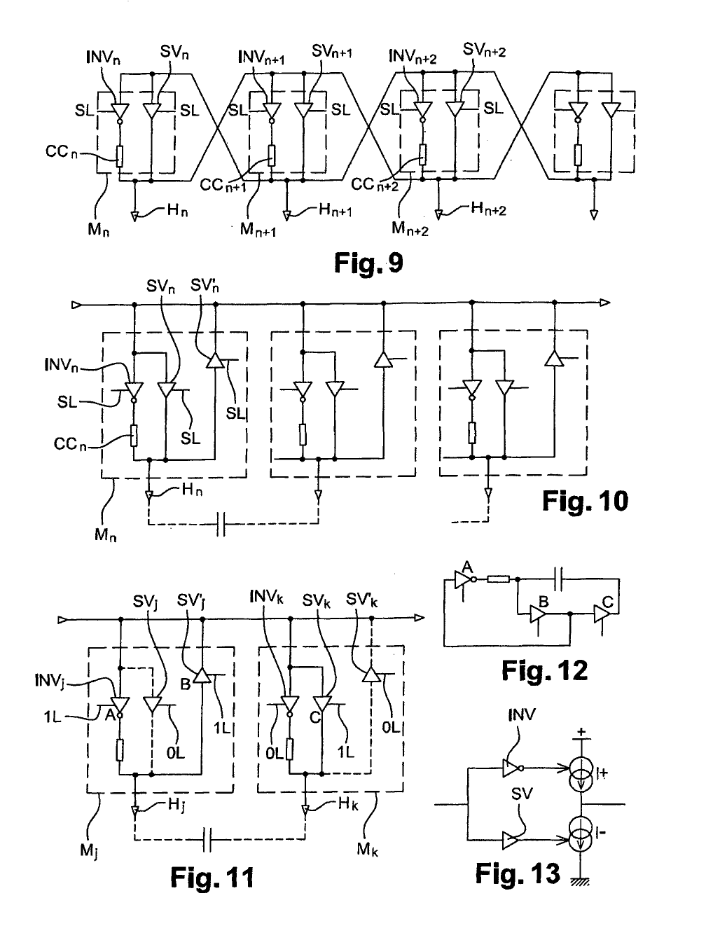

According to a fifth embodiment shown in FIG. 9, an electric diagram is shown which uses controlled gates, i.e. gates having outputs which can represent 3 states, or “tri-states”: a high impedance state and two states corresponding to a logic 1 or O depending on the input signal. This diagram allows selectively forming oscillators in which the same electrode can be a transmitting electrode for a first oscillator formed, and a receiving electrode for a second oscillator formed.

These arrangements allow, particularly in the context of a sensor comprising an electrode matrix structure, performing sensing of the contact position according to a first dimension of the matrix (row or column) in which a contact is present by travelling along the successive electrode pairs according to this first dimension, and then crossing this result with the same course in the second dimension to determine the row and column location of the contact.

Thus, the time required for determining the contact position is substantially reduced compared to an exhaustive course of all the dots formed by intersections of a row electrode and a column electrode.

Indeed, assuming a matrix having a dimension of k columns and I rows, the number of electrode configurations to be analyzed is less than k+I, whereas in the case of an entire course of the matrix, the magnitude order is potentially k*I.

In the case of multiple contacts, a second step may be performed to determine ambiguities between different intersections of rows and column. However, this second step can be performed quickly by point sensing at the intersections determined during the first step and the first step described above still allows significantly improving performance.

As shown in FIG. 9, the device comprises for each electrode Hn an associated module Mn comprising: a first branch comprising a controlled inverter component INVn and a current limiting component CCn, and a second parallel branch comprising a controlled follower component SVn. The output of these two branches is connected both to an electrode Hn and to the input of a module Mn+1 associated with the next electrode Hn+1. The input of a module Mn is connected to the output of the next module Mn+1.

We now consider a configuration in which:
the inverter component INVn of the module Mn is activated;
the follower component SVn of the module Mn is blocked,
the inverter component INVn+1 of the module Mn+1 is blocked, and
the follower component SVn+1 of the module Mn+1 is activated.

In this configuration, it appears that a diagram equivalent to the one in FIG. 1 is obtained, the electrode Hn+1 forming the transmitting electrode and the electrode Hn forming the receiving electrode, the follower component being the follower component of the module Mn+1 and the inverter component being the inverter component INVn, the current limiting component being the component CCn.

In a subsequent configuration of the device, the components are arranged as follows:
the block Mn is deactivated;
the inverter component INVn+1 of the module Mn+1 is activated;
the follower component SVn+1 of the module Mn+1 is blocked,
the inverter component INVn+2 of the module Mn+2 is blocked, and
the follower component SVn+2 of the module Mn+2 is activated.

In this configuration, it appears that a diagram equivalent to the one in FIG. 1 is also obtained, the electrode Hn+2 forming the transmitting electrode and the electrode Hn+1 forming the receiving electrode, the follower component being the follower component of the module Mn+2 and the inverter component being the inverter component INVn+1, the current limiting component being the component CCn+1.

These arrangements allow therefore performing sensing iteratively on a series of electrodes, each electrode acting as receiving and transmitting electrode according to the successive configurations.

The selector SL comprises control inputs of logic components allowing activation or deactivation of said components.

According to a sixth embodiment shown in FIGS. 10 to 12, an electric diagram is shown which also uses controlled gates to allow selectively forming oscillators in which the same electrode can be a transmitting electrode for a first oscillator formed, and a receiving electrode for a second oscillator formed.

Unlike the embodiment shown previously, the purpose here is not to achieve oscillators with two successive electrodes according to one dimension (row or column) of a matrix, but to form an oscillator with two electrodes chosen arbitrarily among all the electrodes which are present.

For this purpose, the device comprises, as shown in FIG. 10 for each electrode Hn an associated module Mn comprising: a first branch comprising a controlled inverter component INVn and a current limiting component CCn, and a second parallel branch comprising a controlled follower component SVn.

The input of these two branches is connected to a common row.

The output of these two branches is connected to an electrode Hn.

A third anti-parallel branch is comprised of a controlled follower component SV′n the input of which is connected to the output of the first two branches, and the output is connected to the common row.

All the inputs of the modules Mn are connected to the common row as well as all the outputs of the follower components SV′n.

We consider now a given configuration shown in FIG. 11 wherein:
an inverter component INVj of a module Mj is activated;
a follower component SVj of the module Mj is blocked,
a follower component SV′j of the module Mj is activated,
the inverter component INVk of the module Mk is blocked,
the follower component SVK of the module MK is activated, and
a follower component SV∝k of the module Mj is blocked.

The other modules are all blocked.

In this configuration, it appears that a diagram equivalent to the one in FIG. 12, itself similar to the one in FIG. 1, is obtained, the electrode Hk forming the transmitting electrode and the electrode Hj forming the receiving electrode, the follower component being the follower component of the module Mk and the inverter component being the inverter component INVj, the current limiting component being the component CCj.

Such a device makes it therefore possible to arbitrarily choose the electrodes forming the transmitting electrode and the receiving electrode respectively.

The selector SL comprises the control inputs of the logic components allowing activation or deactivation of said components.

According to a seventh embodiment, a device according to the invention is adapted to allow operation in front of a screen, in particular TFT/LCD-type screen, which emits electrostatic disturbances.

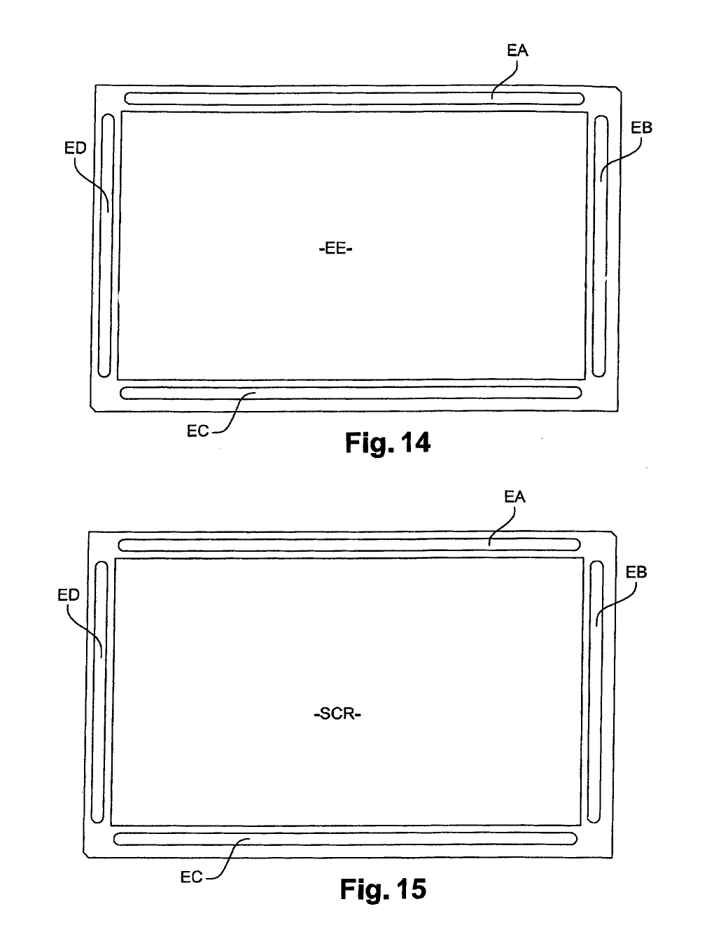

As illustrated in FIG. 14, the electrodes used in this device are disposed as follows:

a central electrode EE is disposed above the screen. This electrode can in particular be formed by an ITO rectangular plate.

This electrode will act as a transmitting electrode. Thus, as it is always connected to a logic gate output (low impedance) corresponding to the output of the follower component SV or buffer B, the disturbances generated by the screen have no effect on its operation.

In this configuration, the analysis comprises in using alternately peripheral electrodes EA, EB, EC and ED as receiving electrodes.

According to an eighth embodiment, a central electrode is no longer desirable. Furthermore, compared to the preceding third to sixth embodiments, it is desired to improve the range and to simplify the structure by having only one peripheral electrode on each side of the screen.

Under these conditions, elongated electrodes EA, EB, EC, ED are disposed on the edges of the screen Scr as illustrated in FIG. 15.

The scanning principle comprises in using alternately an electrode as a transmitting electrode, and using the other electrodes as receiving electrodes. There is therefore a rotation of the choice of the receiving electrode, all the other electrodes being simultaneously transmitting electrodes.

Thus, the following selections are performed repeatedly by the selector SL:

| Receiving Electrode | Transmitting Electrodes |
|---|---|
| EA | EB, EC, ED |
| EB | EA, EC, ED |
| EC | EA, EB, ED |
| ED | EA, EB, EC |

With these arrangements, it is possible to combine the device with an already existing touch system on the surface of the screen.

It appears obviously that the different embodiments detailed above are only examples of implementations of the invention as defined by the appended claims. Variants of these different embodiments can be considered and the different described embodiments can be combined in an easy way by the skilled person. In particular, the voltage amplification component described with reference to the second embodiment can be applied to the other embodiments, by disposing it upstream of the transmitting electrodes.

1. A capacitive sensing device comprising:
logic components and
a capacitive sensor comprising at least one electrode, wherein the logic components and the capacitive sensor being arranged to form an oscillator, and wherein the capacitive sensors comprise a plurality of capacitive sensing electrodes,
the device further comprising a selector arranged to selectively form an oscillator from a plurality of possible oscillators by connecting logic components comprising at least one inverter logic component, and a follower logic component with, respectively, in the case of each oscillator formed, a given combination among the plurality of electrodes of the capacitive sensor comprising at least one transmitting electrode and one receiving electrode forming a capacitance by mutual electrostatic coupling.

2. Device according to claim 1, wherein the selector is arranged to sequentially form different oscillators according to a predefined time sequence.

3. Device according to claim 1, wherein a current limiting component is disposed at the output of the inverter component, between the inverter component and the follower component.

4. Device according to claim 3, wherein the capacitive sensor is disposed in parallel with the follower component.

5. Device according to claim 1, comprising an information feedback loop disposed between the output of the follower component and the input of the inverter component.

6. Device according to claim 1, wherein the plurality of electrodes comprises a receiving electrode or transmitting electrode common to a set of electrode combinations formed among the plurality of electrodes of the capacitive sensor.

7. Device according to claim 1, wherein the plurality of electrodes forms a matrix structure, the selector being arranged to form a set of oscillators each comprising an electrode combination formed by an electrode pair comprised of a transmitting electrode and a receiving electrode.

8. Device according to claim 1, wherein the selector is arranged to form an oscillator with a combination of electrodes comprising a first transmitting electrode, and a second transmitting electrode, a capacitance formed by mutual electrostatic coupling being measured relative to a receiving electrode.

9. Device according to claim 8, wherein the second transmitting electrode is fed in phase with the first transmitting electrode.

10. Device according to any of claims 8, wherein the second transmitting electrode is fed in anti-phase with the first transmitting electrode.

11. Device according to claim 8, wherein the first transmitting electrode and the receiving electrode on the one hand, and the second transmitting electrode on the other hand are disposed on either side of a control surface.

12. Device according to claim 10, wherein a first pair of electrodes and a second pair of electrodes are disposed on either side of the control surface, the selector being arranged to selectively form:
a first oscillator comprising a first transmitting electrode formed by the transmitting electrode of the first pair, and a second transmitting electrode formed by the transmitting electrode of the second pair, a capacitance formed by mutual electrostatic coupling being measured relative to the receiving electrode of the first pair, and
a second oscillator comprising a first transmitting electrode formed by the transmitting electrode of the first pair, and a second transmitting electrode formed by the transmitting electrode of the second pair, a capacitance formed by mutual electrostatic coupling being measured relative to the receiving electrode of the second pair.

13. Device according to claim 8, comprised of a first set of electrodes comprising the first transmitting electrode, the receiving electrode and the second transmitting electrode disposed spaced apart according to a first direction, and a second set comprising a first transmitting electrode, a receiving electrode and a second transmitting electrode disposed spaced apart according to a second direction.

14. Device according to claim 8, comprising logic components distributed in circuit portions associated with an electrode or a combination of electrodes.

15. Device according to claim 14, wherein each circuit portion is disposed close to a pair of electrodes so as to form an oscillator with said pair of electrodes and comprising connections between said circuit portions so as to allow for sensing by a given receiving electrode associated with a circuit portion a transmission by a first transmitting electrode associated with the same circuit portion and a second transmitting electrode supplied by another circuit portion.

16. Device according to claim 1, wherein at least one electrode is used as a transmitting or receiving electrode according to configurations of the device selected by the selector.

17. Device according to claim 16, comprising a plurality of electrodes disposed on the edges of a touch screen.

18. Device according to any of claim 1, comprising an electrode disposed above the screen and several peripheral electrodes.

19. Device according to claim 1, comprising a voltage level adjustment component disposed upstream of a transmitting electrode.

20. Device according to claim 19, wherein the adjustment component is arranged to raise the level of voltage supplied to the transmitting electrode.

21. Device according to claim 19, wherein the adjustment component is arranged to adjust an operating point in terms of the nominal frequency of the oscillator.

22. Device according to claim 1, comprising a signal processing unit for analyzing the characteristics of a signal of the oscillator, and the frequency of the oscillator.
